(19) United States
(12) Patent Application Publication
(10) Pub. No.: US 2026/0269510 A1
(43) Pub. Date: Sep. 10, 2026

(54) ELECTRICAL CONNECTOR AND METHOD OF ABSENCE OF VOLTAGE TEST

(71) Applicant: Caterpillar Inc., Peoria, IL (US)

(72) Inventor: Ben Evans, Peoria, IL (US)

(73) Assignee: Caterpillar Inc., Peoria, IL (US)

(21) Appl. No.: 19/071,891

(22) Filed: Mar. 6, 2025

(51) Int. Cl. H01R 13/44; G01R 19/155; H01R 13/639

(52) U.S. Cl. CPC H01R 13/44; G01R 19/155; H01R 13/639; H01R 2201/20

(57) ABSTRACT

An electrical connector engageable with a complementary electrical connector of an electrical system is disclosed. The electrical connector includes electrical terminal(s), a body, and a cover. The electrical terminal(s) are engageable with corresponding electrical contact(s) of the complementary electrical connector to establish electrical connection(s) therebetween. The body surrounds the electrical terminal(s). The body defines an outer periphery and an opening extending between the outer periphery and the electrical terminal(s). The cover is coupled to the outer periphery. The cover is configured to move between a first position and a plurality of second positions. At the first position, the cover prevents access to the electrical connection through the opening. At the plurality of second positions, the cover allows the sequential access to the electrical connection(s) through the opening for performing absence of voltage test of the electrical connection(s).

### TECHNICAL FIELD

The present disclosure relates to electrical connectors (e.g., plug and receptacle connectors) used in electrical systems. More particularly, the present disclosure relates to an electrical connector facilitating absence-of-voltage test of an associated electrical system.

### BACKGROUND

Work Machines, such as compactors, pavers, haul trucks, dozers, motor graders, excavators, wheel loaders, and other types of equipment are widely used in various construction, mining, and agricultural applications. These machines are equipped with various electrical systems and components such as motors, voltage converters, and the like. These systems are electrically connected to an onboard electrical power source (e.g., fuel cell or battery), via connectors, to receive power from the onboard power source and perform operations of the machines. They may also be intermittently connected to an offboard power source for charging.

Because the work machines often operate in harsh environments involving water, mud, and abrasive contaminants, periodic servicing of the electrical system (and its components, connectors) are required to maintain operational efficiency and safety. An operator or service technician of the work machine may need to test and ensure absence of voltage at key points within the electrical system and/or the connectors before accessing the electrical system e.g. opening enclosures or removing guarding of the systems, to perform service on the system or any components.

German Patent Publication No. 102013014178 discloses a contacting device with two corresponding contacting units. The contacting units contain electrical contact elements. The first contact element is designed as a socket and the second contact element is designed as a plug contact that can be inserted into the socket. An outer side of the first contact element has an electrical insulation. The first contacting unit has at least one measuring access which is designed as a feedthrough opening in the electrical insulation and a socket wall of the first contact element.

### SUMMARY OF THE INVENTION

In one aspect, the disclosure relates to an electrical connector. The electrical connector is engageable with a complementary electrical connector of an electrical system. The electrical connector includes one or more electrical terminals, a body, and a cover. The one or more electrical terminals are engageable with corresponding one or more electrical contacts of the complementary electrical connector to establish a plurality of electrical connections therebetween. For instance, an exemplary electrical connection within the connector may be formed between multiple conductors including positive and negative phases, earth, and other reference conductors. The body surrounds the one or more electrical terminals. The body defines an outer periphery and an opening extending between the outer periphery and the one or more electrical terminals. The cover is coupled to the outer periphery. The cover is configured to move between a first position and a plurality of second positions. At the first position, the cover prevents access to the plurality of electrical connections through the opening. At the plurality of second positions, the cover allows the sequential access to the plurality of electrical connections through the opening for performing absence of voltage test of the plurality of electrical connections.

In another aspect, the disclosure is directed to a method for absence of voltage test of an electrical system. The method includes using an electrical connector of the electrical system. The electrical connector includes one or more electrical terminals, a body, and a cover. The one or more electrical terminals are engageable with corresponding one or more electrical contacts of a complementary electrical connector of the electrical system to establish a plurality of electrical connections therebetween. The body surrounds the one or more electrical terminals and defines an outer periphery and an opening extending between the outer periphery and the one or more electrical terminals. The cover is coupled to the outer periphery and configured to move between a first position to prevent an access to the plurality of electrical connections through the opening and a plurality of second positions to allow sequential access to the plurality of electrical connections through the opening. Further, the method includes moving the cover from the first position to the plurality of second positions to access the opening. Furthermore, the method includes inserting a testing probe through the opening to contact the testing probe with the one or more electrical terminals for performing the absence of voltage test of the electrical connections.

In yet another aspect, the disclosure relates to a work machine. The work machine includes an electrical system configured to perform one or more functions associated with an operation of the work machine, an electrical power source for powering the electrical system, and an electrical connector unit. The electrical connector unit includes a receptacle connector and a plug connector. The receptacle connector is electrically coupled to the electrical system. The receptacle connector includes one or more electrical contacts. The plug connector is electrically coupled to the power source and engageable with the complementary receptacle connector. The plug connector includes one or more electrical terminals, a body, and a cover. The one or more electrical terminals is engageable with the corresponding one or more electrical contacts to establish a plurality of electrical connections therebetween for electrical supply between the electrical power source and the electrical system. The body surrounds the one or more electrical terminals. The body defines an outer periphery and an opening extending between the outer periphery and the one or more electrical terminals. The cover is coupled to the outer periphery and configured to move between a first position and a plurality of second positions. At the first position, the cover prevents access to the electrical connections through the opening. At the plurality of second positions, the cover facilitates sequential access to the plurality of electrical connections through the opening for performing absence of voltage test of the electrical connections.

### BRIEF DESCRIPTION OF THE DRAWINGS

FIG. 1 is a side view of a work machine including an electrical connector unit electrically connecting an electrical system with an electrical power source of the work machine, in accordance with an embodiment of the present disclosure;

FIG. 2 illustrates a cross-sectional view of an electrical connector (e.g., a plug connector) of the electrical connector unit disconnected from a complementary electrical connector (e.g., a receptacle connector) of the electrical connector unit, in accordance with an embodiment of the present disclosure;

FIG. 3 illustrates a cross-sectional view of the electrical connector connected with the complementary electrical connector, with the electrical connector in a first configuration preventing absence of voltage test, in accordance with an embodiment of the present disclosure;

FIG. 4 illustrates a cross-sectional view of the electrical connector connected with the complementary electrical connector, with the electrical connector in a second configuration allowing absence of voltage test, in accordance with an embodiment of the present disclosure;

FIG. 5 illustrates a cross-sectional view of the electrical connector in the second configuration with a testing probe in contact with one or more electrical terminals of the electrical connector for performing the absence of voltage test, in accordance with an embodiment of the present disclosure;

FIG. 6 illustrates a cross-sectional view of an electrical connector to be connected with a complementary electrical connector, in accordance with another embodiment of the present disclosure; and

FIG. 7 is a flowchart illustrating a method for absence of voltage test, in accordance with an embodiment of the present disclosure.

### DETAILED DESCRIPTION

Reference will now be made in detail to specific embodiments or features, examples of which are illustrated in the accompanying drawings. Generally, corresponding reference numbers may be used throughout the drawings to refer to the same or corresponding parts, e.g., 1, 1′, 1″, 101 and 201 could refer to one or more comparable components used in the same and/or different depicted embodiments.

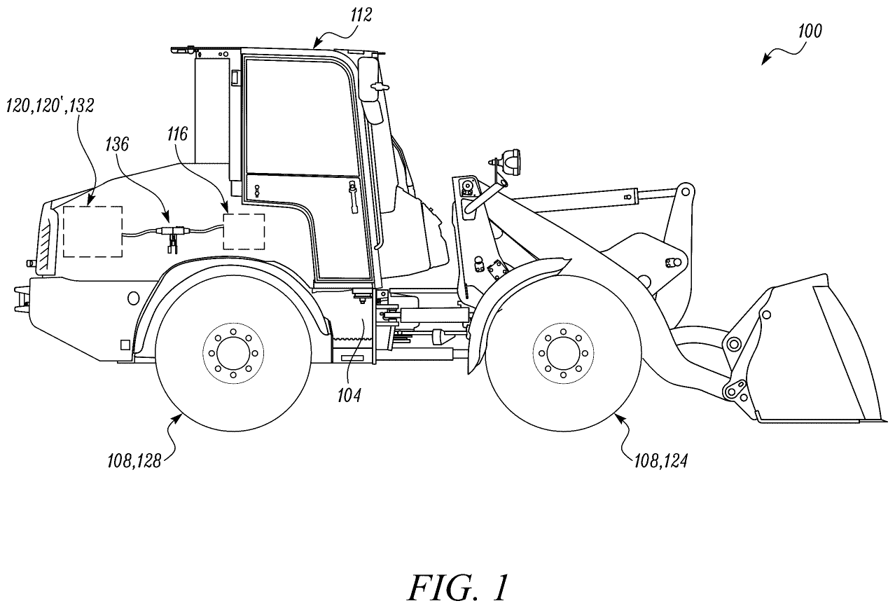

Referring to FIG. 1, an exemplary work machine 100 (hereinafter referred to as “machine 100”) is shown. The machine 100 operates at a worksite that may include a mine site, a landfill, a quarry, a construction site, or any other type of worksite. In one example, the machine 100 may be a wheel loader, although one or more aspects of the present disclosure may be applied to other machines, such as off-highway trucks, haul trucks, dump trucks, excavators, dozers, and/or the like. Further, the machine 100 may be a manned machine or an unmanned machine. In another example, the machine 100 may be a stationary machine, such as a containerized power module.

The machine 100 may include a frame 104, ground engaging members 108, and an operator cabin 112. Further, the machine 100 includes one or more electrical systems 116 and a power source 120. The frame 104 may accommodate and/or support the operator cabin 112 and the electrical system 116, although other known components and structures may be supported by the frame 104, as well. The ground engaging members 108 may support the machine 100 on ground at the worksite. The ground engaging members 108 may include a set of front wheels 124 and a set of rear wheels 128. In other embodiments, the ground engaging members 108 may include crawler tracks (not shown) provided either alone or in combination with the wheels 124, 128.

The operator cabin 112 may be supported over the frame 104. The operator cabin 112 may facilitate stationing of one or more operators therein, to monitor the operations of the machine 100. Also, the operator cabin may house various components and controls of the machine 100, access to one or more of which may help the operators to control the machine's movement and/or operation. For example, the various components and controls of the machine 100 may include one or more steering wheels, braking pedals, accelerating pedals, joysticks, switches etc., to facilitate an operator in operating the machine 100.

The electrical system 116 may be configured to perform one or more functions associated with an operation of the machine 100. For example, the electrical system 116 may be a hazardous-voltage electrical system configured to output a modified (or modulated) electrical power to be supplied to the systems or assemblies, for example, to one or more electric drive motors (not shown) connected to the ground engaging members 108 for propelling or retarding the machine 100. Examples of the hazardous-voltage electrical system may include, but not limited to, a rectifier system and an inverter system.

The power source 120 may be an electrical power source 120′ configured to supply electrical power (e.g., direct current, or alternating current) to the electrical system 116, for example, to enable the electrical system 116 to perform the functions associated with the operation of the machine 100. The electrical power source 120′ may be a hazardous voltage battery pack 132. The battery pack 132 may include energy storage cells (not shown). The battery pack 132 may also include electrical and/or electronic components, such as busbars, a battery management system, and the like. It should be noted that construction and functionality of such electrical and/or electronic components are known in the art, and therefore, they are not discussed.

The power source 120 (e.g., the hazardous-voltage battery pack 132) may be configured to store and supply electrical energy to power operations, for example, of the electrical system 116 of the machine 100. To transmit the electrical energy between the power source 120 and the electrical systems 116, in one or more aspects of the present disclosure, an electrical connector unit 136 is disclosed. The electrical connector unit 136 provides one or more electrical connections between the power source 120 and the electrical system 116 of the machine 100. Also, the electrical connector unit 136 allows the manufacturer and/or the operator to perform absence of voltage test of the electrical connection. The electrical connector unit 136 includes an electrical connector 140 (hereinafter referred to as “connector 140”). In addition, the electrical connector unit 136 includes a complementary electrical connector 144 (hereinafter referred to as “complementary connector 144”).

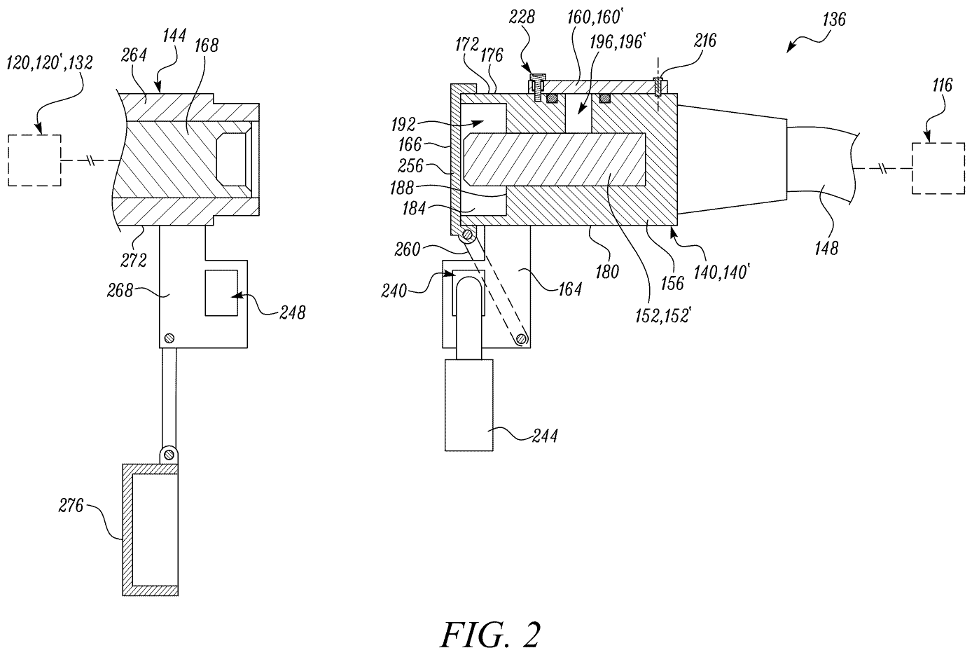

The connector 140 is now discussed. The connector 140 is configured to be electrically coupled to the electrical system 116 to define a path for electrical supply (e.g., from the electrical power source 120) therethrough. In an example, as shown in FIG. 2, the connector 140 is electrically coupled to the electrical system 116, via one or more electrical conductors 148 extending between the connector 140 and the electrical system 116. Alternatively, the connector 140 may be mounted directly to the electrical system 116 (e.g., to the power inverter of the machine 100) reducing the need for additional wiring. In an embodiment, as shown in FIG. 2, the connector 140 is a plug connector 140′. In another embodiment, the connector 140 may be a receptacle connector.

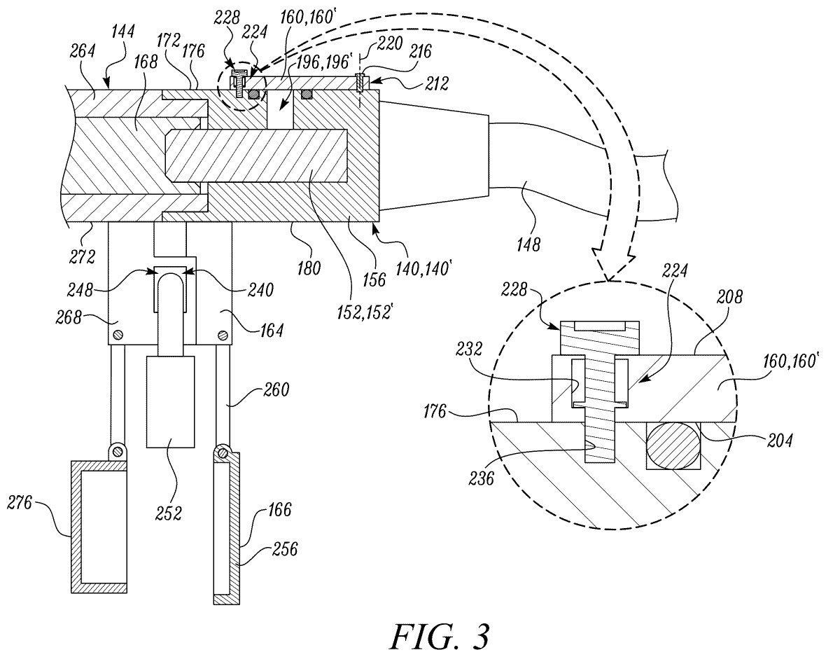

Referring to FIGS. 2 and 3, the connector 140 (or the plug connector 140′) includes one or more electrical terminals 152, a body 156, and a cover 160. Further, in some embodiments, the connector 140 may include a protruded portion 164 and a cap 166. Each of the electrical terminals 152, the body 156, the cover 160, the protruded portion 164, and the cap 166 is now discussed in detail below.

The electrical terminals 152 may include conductive pins 152′ electrically coupled to the one or more electrical conductors 148 to allow the electrical energy supply to pass therethrough, to the electrical system 116. Further, the electrical terminals 152 may be engageable with corresponding one or more electrical contacts 168 of the complementary connector 144 to establish one or more electrical connections therebetween. In an example, the connector 140 may include one electrical terminal 152. In another example, the connector 140 may include multiple electrical terminals 152 which are arranged in any suitable pattern, for example, in a linear, circular or staggered pattern. In another embodiment, the connector 140 includes electrical terminals 152 that are electrically coupled to one or more electrical conductors 148 to provide equipotential bonding with the electrical system 116. In yet another embodiment, the connector 140 includes electrical terminals 152 that are electrically coupled to one or more electrical conductors 148 that are used to distribute a reference voltage in the electrical system 116.

The body 156 surrounds the electrical terminal(s) 152. The body 156 defines an outer periphery 172 surrounding the electrical terminal(s) 152. The outer periphery 172 may define a top wall portion 176 and a bottom wall portion 180. In an example, the bottom wall portion 180 may be disposed parallel to and spaced from the top wall portion 176. In addition, the outer periphery 172 may define side wall portions (only one side wall portion 184 shown in FIG. 2) that may extend between the top wall portion 176 and the bottom wall portion 180. In addition, the body 156 may include a mating surface 188 and an inner cavity 192. The mating surface 188 may define location(s) (not shown) through which the corresponding electrical terminal(s) 152 extend out of the body 156. The mating surface 188 along with the top wall portion 176, the bottom wall portion 180, and the sidewall portions 184 may define the inner cavity 192. The inner cavity 192 may receive the electrical terminal(s) 152 extending out (of the body 156) through the mating surface 188.

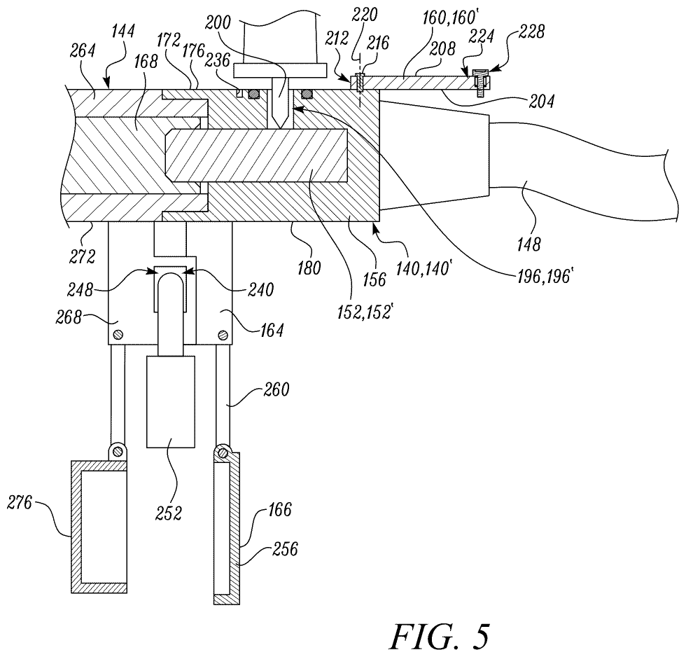

Further, the body 156 includes one or more openings 196. The openings 196 may be one or more through-holes 196′ that extend between the outer periphery 172 and the corresponding electrical terminal(s) 152. In an example in which the connector 140 includes one electrical terminal 152, one opening 196 may be defined on the body 156. In another example in which the connector 140 includes multiple electrical terminals 152, multiple openings (similar to the opening 196) may be defined on the body 156, and each such opening extends between the outer periphery 172 and the corresponding electrical terminal 152. In an embodiment, as shown in FIG. 2, the opening 196 extends between the top wall portion 176 (of the outer periphery 172) and the electrical terminal 152. In other embodiments, the opening 196 may extend between any wall portion (e.g., the bottom wall portion 180, or the sidewall portion 184) of the body 156 and the electrical terminal 152. The opening 196 is configured to receive, for example, a testing probe 200 (as shown in FIG. 5) for performing absence of voltage test of the connector 140 and the electrical system 116.

The cover 160 may be a flat plate 160′. As shown in FIG. 3, the cover 160 (or the flat plate 160′) may define a first surface 204 and a second surface 208 opposite to the first surface 204. The first surface 204 may face towards the outer periphery 172, whereas the second surface 208 may face away from the outer periphery 172. In an example, the first surface 204 faces towards and is in contact with the top wall portion 176 of the body 156, as shown in FIG. 3.

The cover 160 (or the flat plate 160′) is coupled to the outer periphery 172 of the body 156. The cover 160 may be pivotably coupled, at its first portion 212, to the outer periphery 172 (e.g., to the top wall portion 176), via a hinge joint 216. The hinge joint 216 may allow the cover 160 to pivot (or rotate) relative to the body 156 about a pivoting axis 220. Further, the cover 160 may be removably coupled, at its second portion 224, to the outer periphery 172 (e.g., to the top wall portion 176), for example, via a fastener 228. To this end, the cover 160 may include a through-hole 232.

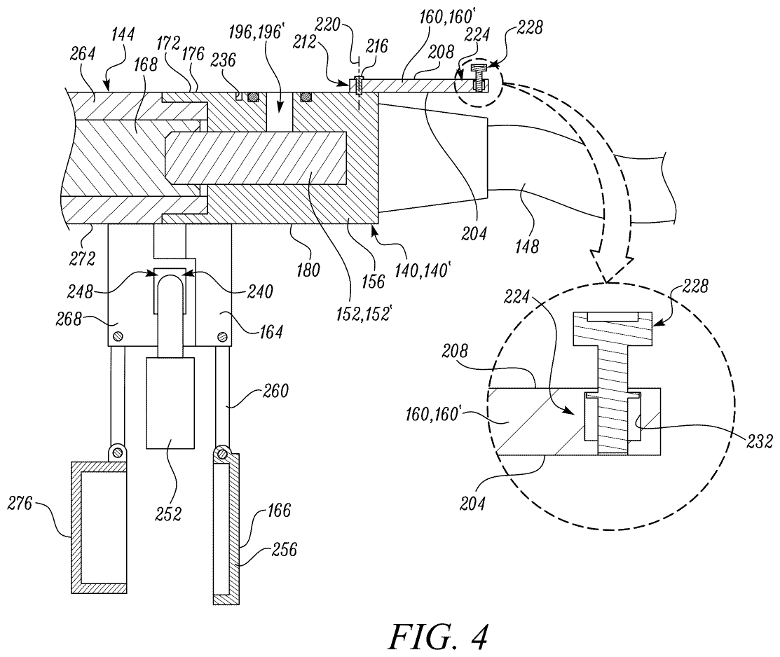

The cover 160 (or the flat plate 160′) is configured to move (e.g., pivot about the pivoting axis 220) between a first position (or a closed position) (as shown in FIG. 3) and a plurality of second positions (or open positions) (one of the second positions is shown in FIG. 4). At the first position, the cover 160 may be coupled with the outer periphery 172 (of the body 156), via the fastener 228. In an exemplary coupling of the cover 160 with the outer periphery 172 of the body 156, the cover 160 may be moved to its first position at which the through-hole 232 (of the cover 160) (as shown in FIG. 3) may be aligned with a corresponding mounting hole 236 (of the body 156) (as shown in FIG. 3), and the fastener 228 may be threadably received within the through-hole 232 and the mounting hole 236 to sealably and removably couple the cover 160 with the outer periphery 172 of the body 156. When coupled with the outer periphery 172, at the first position, the cover 160 sealably closes the opening 196 to prevent access to the electrical terminal(s) 152, and hence to the electrical connection(s) defined between the electrical terminal(s) 152 and the electrical contact(s) 168 (of the complementary connector 144), through the opening 196.

To move from its first position to one of its second position, the cover 160 may be decoupled (at its second portion 224) from the outer periphery 172 (of the body 156), for example, by unfastening the fastener 228. Once unfastened, the fastener 228 may be retained within the through-hole 232 when the second portion 224 of the cover 160 is decoupled from the outer periphery 172, as shown in FIG. 4. At the second positions, the cover 160 allows sequential access to the electrical connections (e.g., defined between the electrical terminal(s) 152 and the electrical contact(s) 168 of the complementary connector 144) through the opening 196 for performing the absence of voltage test of the electrical connection(s).

Additionally, a biasing member, such as a spring, or a resilient material, may be coupled with the cover 160 and the body 156 of the connector 140. The biasing member may be configured to bias the cover 160 to one of its first position and second positions. In one example, the biasing member may bias the cover 160 to one of the second positions (or open positions). In another example, the biasing member may bias the cover 160 to its first position (or closed position).

The protruded portion 164 may extend outwardly from the outer periphery 172 of the body 156 (of the connector 140). In an example, as shown in FIG. 2, the protruded portion 164 may extend outwardly from the bottom wall portion 180 of the body 156. It should be noted that, in other embodiments, the protruded portion 164 may extend outwardly from the top wall portion 176, or the sidewall portion 184, of the body 156.

The protruded portion 164 may define an eyelet 240. The eyelet 240 may be configured to receive one or more locking members. In one example, the eyelet 240 may be configured to receive a locking member 244 to lock the cap 166 in a position to cover the inner cavity 192 and terminal 152 (as shown in FIG. 2). In another example, the eyelet 240 may be configured to be aligned with a corresponding securing portion of the complementary connector 144 (e.g., an eyelet 248) and receive a locking member 252 to secure the connector 140 with the complementary connector 144 when the electrical terminal(s) 152 are engaged with the corresponding electrical contact(s) 168 to establish the electrical connection therebetween (as shown in FIG. 3). The locking member 252 may be the same as the locking member 244. The locking members 244, 252 may be a padlock.

The cap 166 may include a body 256 and an arm portion 260. The body 256 may be a C-shaped body 256′ configured to be removably engaged with the outer periphery 172 of the connector 140, for example, to close the inner cavity 192 of the connector 140. The arm portion 260 may extend between the body 256 and the protruded portion 164. In an example, the arm portion 260 may be pivotably coupled, at one end, to the body 256, and may be pivotably coupled, at the other end, to the protruded portion 164.

The cap 166 is moveable between a covered position (as shown in FIG. 2) and an uncovered position (as shown in FIGS. 3, 4 & 5). At the uncovered position, the cap 166 may be configured to allow access into the inner cavity 192 for the engagement of the electrical terminal(s) 152 with the corresponding electrical contact(s) 168 to establish the electrical connection therebetween the connector 140 and the complementary connector 144. At the covered position, the cap 166 is configured to sealably close the inner cavity 192 when the connector 140 is disengaged with the complementary connector 144.

The complementary connector 144 is now discussed with reference to FIGS. 2 and 3. The complementary connector 144 is a receptacle connector 144′ configured to be engaged with the corresponding plug connector 140′ (i.e., the connector 140) to establish the electrical connections therebetween. The complementary connector 144 may include the electrical contacts 168 engageable with corresponding electrical terminals 152, a body 264 surrounding the electrical contacts 168, a protruded portion 268 extending outwardly from an outer periphery 272 of the body 264 to define the eyelet 248, and a cap 276 removably engaged with the body 264 to cover the electrical contacts 168 when the complementary connector 144 is in a disengaged state (as shown in FIG. 2). In an example, the cap 276 may be pivotably coupled with the protruded portion 268.

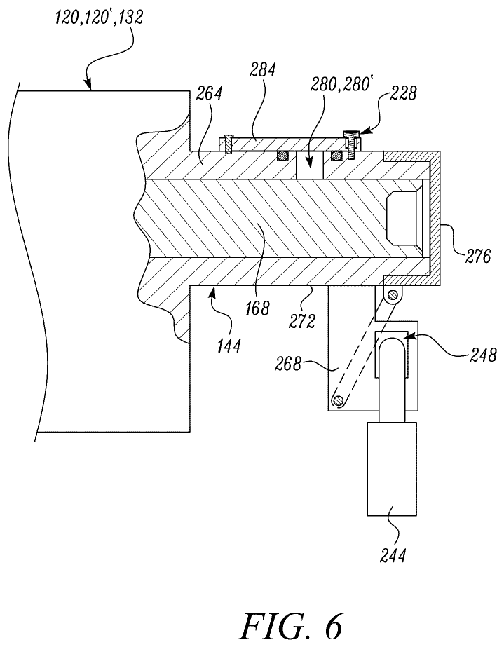

Further, in an embodiment, as shown in FIG. 6, the complementary connector 144 may be mounted directly to the power source 120, 120′, 132 (e.g., to the battery of the machine 100). The complementary connector 144 (i.e., the receptacle connector 144′) may also include an opening 280 (similar to the opening 196). The opening 280 may be a through-hole 280′ that extend between the outer periphery 272 and the electrical contacts 168. The opening 280 may be configured to receive, for example, the testing probe 200 for performing absence of voltage test of the electrical connection(s) between the connector 140 and the complementary connector 144. Furthermore, a cover 284 (of the complementary connector 144) may be coupled to the outer periphery 272 of the complementary connector 144 in a same manner as the cover 160 (as shown in FIG. 2) is coupled to the outer periphery 172 of the connector 140. Accordingly, the cover 284 may move between its closed position to sealably close the opening 280 to prevent access to the electrical contacts 168, and its open position to allow the access to the electrical contacts 168 through the opening 280 for performing the absence of voltage test of the electrical connections.

### Industrial Applicability

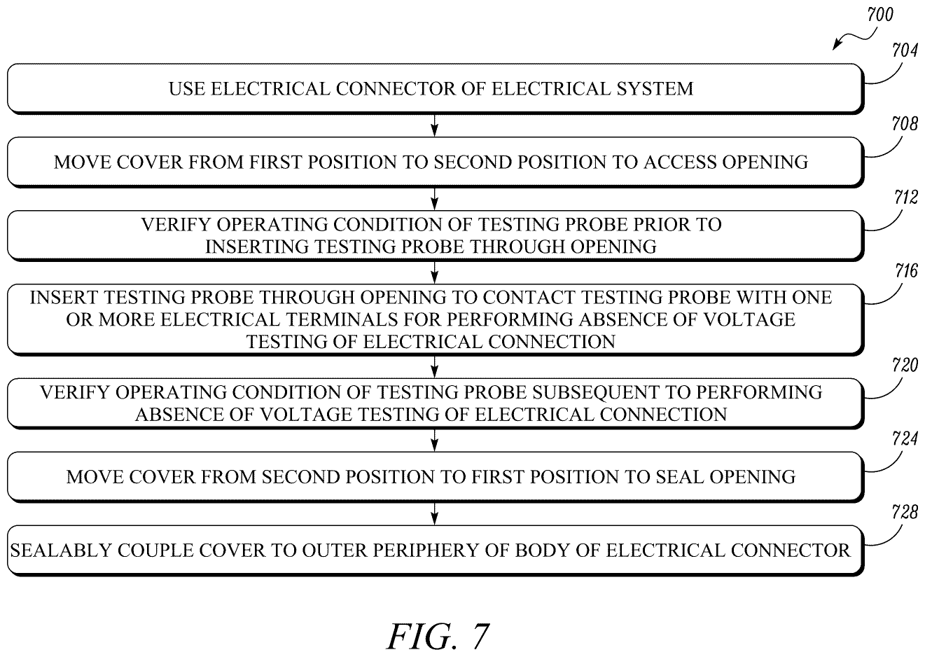

Referring to FIG. 7, an example method for absence of voltage test of the electrical system 116 is discussed. The method discussed by way of a flowchart 700 that illustrates exemplary stages (e.g., from 704 to 728) associated with the method. The method is also discussed in conjunction with FIGS. 1-5. It will be appreciated that the description in the method is exemplary in nature and that the steps can be performed in different executable details than what is set out below, as will be contemplated by a person skilled in the art based on the description of the present disclosure.

The method includes using the connector 140 (e.g., the plug connector 140′, shown in FIGS. 1-5) of the electrical system 116 for performing the absence of voltage test (step 704). The connector 140 provides one or more electrical terminals 152 engaged with the corresponding one or more electrical contacts 168 of the complementary connector 144 (e.g., electrically coupled with the power source 120) to establish electrical connection(s) therebetween. Further, the connector 140 has the body 156 that surrounds the electrical terminal(s) 152. The body 156 defines the opening 196 that extends between the outer periphery 172 (of the body 156) and the electrical terminal(s) 152. Also, the connector 140 provides the cover 160 that is coupled to the outer periphery 172, and is movable between its first position (i.e., closed position, shown in FIG. 3) to prevent the access to the electrical terminal(s) 152 through the opening 196 and one of its second positions (e.g., an open position as shown in FIG. 4) to allow the access to the electrical terminal(s) 152 through the opening 196. Although the connector 140 (e.g., the plug connector 140′) is selected for performing the absence of voltage test, it should be noted that, in an alternate embodiment, the method may include using the complementary connector 144 (e.g., the receptacle connector 144′, as shown in FIG. 6) of the electrical system 116 for performing the absence of voltage test.

Further, the method includes moving the cover 160 from the first position to one of the second positions to access the opening 196 (step 708). To this end, the cover 160 may be decoupled from the outer periphery 172 (of the connector 140) by unfastening the fastener 228. Once the fastener 228 is unfastened and the cover 160 is decoupled from the outer periphery 172, the fastener 228 may be retained with the through-hole 232 of the cover 160, as shown in FIG. 4. Once decoupled from the outer periphery 172, the cover 160 may be pivoted (or rotated) about the pivoting axis 220 from the first position to one of the second positions to provide sequential access to the electrical terminal(s) 152 through the opening 196.

The method further includes verifying an operating condition of the testing probe 200 prior to inserting the testing probe 200 through the opening 196 for performing the absence of voltage test (step 712). For that, the testing probe 200 may be tested on a known live voltage source to verify that the testing probe 200 is functioning properly. In an example, the known live voltage source may be the reference voltage provided within the connector 140.

Subsequent to verifying the proper functioning of the testing probe 200, the method includes inserting the testing probe 200 through the opening 196 to contact the test probe 200 with the electrical terminal(s) 152 for performing the absence of voltage test of the electrical connection(s) (step 716). At this stage, the electrical terminals 152 remain engaged with the corresponding electrical contacts 168 (of the complementary connector 144).

Subsequent to performing the absence of voltage test of the electrical connection via inserting the testing probe 200 through the opening 196, the method includes verifying the operating condition of the testing probe 200 (step 720). For that, the testing probe 200 may be tested on a known live voltage source to verify and confirm that the testing probe 200 was functioning properly after the absence of voltage test. Once the absence of voltage test is complete, the method includes moving the cover 160 from said second position (of the multiple second positions) to the first position about the pivoting axis 220 to align the through-hole 232 (of the cover 160) with the mounting hole 236 (of the body 156) (step 724). Once the cover 160 is moved to its first position, the method further includes fastening the fastener 228 to the mounting hole 236 (of the body 156) to sealably couple the cover 160 to the outer periphery 172 of the connector 140 to seal the opening 196 (step 728). Once the steps 704 to 728 are completed to verify that a safe electrical work environment exists in the electrical system 116, the electrical connector unit 136 may be disengaged (e.g., for servicing), or engaged for establishing the electrical connection(s).

The disclosed connector 140 (or the complementary connector 144) may be applicable to any work machine (such as the machine 100) that includes at least one electrical power source (such as the high-voltage electrical power source 120) and at least one electrical system (such as the electrical system 116). The connector 140 (or the complementary connector 144) eliminates a need to use (or mount) extra absence of voltage check points (or devices) for performing the absence of voltage test.

Further, the electrical connector unit 136 comprising of connector 140 and complementary connector 144, provides a simple and cost-effective solution for establishing electrical connections between the electrical system 116 and the electrical power source 120 as well as performing the absence of voltage test of the electrical connections without a need to decouple the electrical system 116 from the electrical power source 120. Accordingly, the electrical connector unit 136 comprising of connector 140 and/or complementary connector 144, and the method outlined in this disclosure, eliminates any possible arc flash hazards in case the electrical system 116 is decoupled from the electrical power source 120 while the electrical connection system is live prior to performing the absence of voltage test.

Furthermore, the disclosed connector 140 (or the complementary connector 144) provides the cover 160 to sealably close the opening 196 (used to receive the testing probe 200 for performing the absence of voltage test) when the connector 140 is used to transmit electrical energy between the electrical system 116 and the electrical power source 120. By sealably closing the opening 196, the cover 160 may mitigate a risk of forming any potential leak path for pollution, including moisture or dust ingression, within the connector 140.

Unless explicitly excluded, the use of the singular to describe a component, structure, or operation does not exclude the use of plural such components, structures, or operations or their equivalents. The use of the terms “a” and “an” and “the” and “at least one” or the term “one or more,” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B” or one or more of A and B”) is to be construed to mean one item selected from the listed items (A or B) or any combination of two or more of the listed items (A and B; A, A and B; A, B and B), unless otherwise indicated herein or clearly contradicted by context. Similarly, as used herein, the word “or” refers to any possible permutation of a set of items. For example, the phrase “A, B, or C” refers to at least one of A, B, C, or any combination thereof, such as any of: A; B; C; A and B; A and C; B and C; A, B, and C; or multiple of any item such as A and A; B, B, and C; A, A, B, C, and C; etc.

It will be apparent to those skilled in the art that various modifications and variations can be made to the electrical connector, the method and/or the work machine of the present disclosure without departing from the scope of the disclosure. Other embodiments will be apparent to those skilled in the art from consideration of the specification and practice of the enclosure, the electrical connector, the method and/or the work machine disclosed herein. It is intended that the specification and examples be considered as exemplary only, with a true scope of the disclosure being indicated by the following claims and their equivalent.

What is claimed is:

1. An electrical connector engageable with a complementary electrical connector of an electrical system, the electrical connector comprising:
one or more electrical terminals engageable with corresponding one or more electrical contacts of the complementary electrical connector to establish a plurality of electrical connections therebetween;
a body surrounding the one or more electrical terminals, the body defining an outer periphery and an opening extending between the outer periphery and the one or more electrical terminals; and
a cover coupled to the outer periphery and configured to move between a first position and a plurality of second positions, wherein:
at the first position, the cover prevents access to the electrical connection through the opening, and
at the plurality of second positions, the cover allows the sequential access to the plurality of electrical connections through the opening for performing absence of voltage test of the plurality of electrical connections.

2. The electrical connector of claim 1 further including a protruded portion extending outwardly from the outer periphery and defining an eyelet configured to receive one or more locking members to secure the electrical connector with the complementary electrical connector when the one or more electrical terminals are engaged with the corresponding one or more electrical contacts to establish the plurality of electrical connections therebetween.

3. The electrical connector of claim 1, wherein the body includes a mating surface, and an inner cavity defined between the outer periphery and the mating surface to receive the one or more electrical terminals extending through the mating surface, the electrical connector including:
a cap moveable between an uncovered position and a covered position, wherein:
at the uncovered position, the cap is configured to allow access into the inner cavity for the engagement of the one or more electrical terminals with the corresponding one or more electrical contacts to establish the plurality of electrical connections therebetween, and
at the covered position, the cap is configured to sealably close the inner cavity when the one or more electrical terminals of the electrical connector are disengaged with the corresponding one or more electrical contacts of the complementary electrical connector.

4. The electrical connector of claim 3 further including a protruded portion extending outwardly from the outer periphery and defining an eyelet, wherein the cap is pivotably coupled to the protruded portion to move between the covered position and the uncovered position, and wherein the eyelet is configured to receive one or more locking members to lock the cap at the uncovered position of the cap.

5. The electrical connector of claim 1, wherein the cover is pivotably coupled at its first portion to the outer periphery, the cover including a through-hole defined at a second portion distant from the first portion, and the body including a mounting hole, wherein:
at the first position of the cover, the through-hole is configured to align with the mounting hole to receive a fastener therethrough to couple the cover to the outer periphery, and
at one of the plurality of second positions of the cover, the through-hole is configured to retain the fastener when the cover is decoupled from the outer periphery for performing the absence of voltage test of the electrical connection.

6. The electrical connector of claim 1, wherein the electrical connector is a plug connector.

7. The electrical connector of claim 1, wherein the electrical connector is a receptacle connector.

8. A method for absence of voltage testing of an electrical system, the method comprising:
using an electrical connector of the electrical system, the electrical connector including:
one or more electrical terminals engageable with corresponding one or more electrical contacts of a complementary electrical connector of the electrical system to establish a plurality of electrical connection therebetween;
a body surrounding the one or more electrical terminals and defining an outer periphery and an opening extending between the outer periphery and the one or more electrical terminals; and
a cover coupled to the outer periphery and configured to move between a first position to prevent an access to the plurality of electrical connections through the opening and a plurality of second positions to allow sequential access to the plurality of electrical connections through the opening;
moving the cover from the first position to one of the plurality of second positions to access the opening; and
inserting a testing probe through the opening to contact the testing probe with the one or more electrical terminals for performing the absence of voltage test of the plurality of electrical connections.

9. The method of claim 8, wherein the cover is pivotably coupled at its first portion to the outer periphery, the cover including a through-hole defined at a second portion distant from the first portion, and the body including a mounting hole, wherein, at the first position of the cover, the through-hole is aligned with the mounting hole and a fastener is received therethrough to couple the cover to the outer periphery, and wherein moving the cover from the first position to one of the plurality of second positions includes:
decoupling the cover from the outer periphery by unfastening the fastener, wherein the fastener is retained with the through-hole of the cover after the cover is decoupled from the outer periphery; and
moving the cover from the first position to one of the plurality of second positions about a pivoting axis to provide access to the one or more electrical terminals through the opening.

10. The method of claim 9 further including:
verifying an operating condition of the testing probe prior to and subsequent to inserting the testing probe through the opening for performing the absence of voltage test;
moving the cover from one of the plurality of second positions to the first position about the pivoting axis to align the through-hole with the mounting hole subsequent to verifying the operating condition of the testing probe after performing the absence of voltage test; and
fastening the fastener to the mounting hole of the body to sealably couple the cover to the outer periphery of the body.

11. The method of claim 10, wherein the electrical connector includes a protruded portion extending outwardly from the outer periphery and defining an eyelet configured to receive one or more locking members to secure the electrical connector with the complementary electrical connector when the one or more electrical terminals are engaged with the corresponding one or more electrical contacts to establish the plurality of electrical connections therebetween.

12. The method of claim 10, wherein the body includes a mating surface, and an inner cavity defined between the outer periphery and the mating surface to receive the one or more electrical terminals extending through the mating surface, the electrical connector further including:
a cap moveable between an uncovered position and a covered position, wherein:
at the uncovered position, the cap is configured to allow access into the inner cavity for the engagement of the one or more electrical terminals with the corresponding one or more electrical contacts to establish the electrical connection therebetween, and
at the covered position, the cap is configured to sealably close the inner cavity when the one or more electrical terminals of the electrical connector are disengaged with the corresponding one or more electrical contacts of the complementary electrical connector.

13. The method of claim 12, wherein the electrical connector includes a protruded portion extending outwardly from the outer periphery and defining an eyelet, wherein the cap is pivotably coupled to the protruded portion to move between the covered position and the uncovered position, and wherein the eyelet is configured to receive one or more locking members to lock the cap at the uncovered position of the cap.

14. The method of claim 8, wherein the electrical connector is a plug connector.

15. The method of claim 8, wherein the electrical connector is a receptacle connector.

16. A work machine, comprising:
an electrical system configured to perform one or more functions associated with an operation of the work machine;
an electrical power source for powering the electrical system; and
an electrical connector unit including:
a receptacle connector electrically coupled to the electrical system, the receptacle connector including one or more electrical contacts; and
a plug connector electrically coupled to the power source and engageable with the complementary receptacle connector, the plug connector including:
one or more electrical terminals engageable with the corresponding one or more electrical contacts to establish a plurality of electrical connections therebetween for electrical supply between the electrical power source and the electrical system;
a body surrounding the one or more electrical terminals, the body defining an outer periphery and an opening extending between the outer periphery and the one or more electrical terminals; and
a cover coupled to the outer periphery and configured to move between a first position and a plurality of second positions, wherein:
at the first position, the cover prevents access to the electrical connection through the opening, and
at the plurality of second positions, the cover facilitates sequential access to the plurality of electrical connections through the opening for performing absence of voltage test of the plurality of electrical connections.

17. The work machine of claim 16, wherein the plug connector includes a protruded portion extending outwardly from the outer periphery and defining an eyelet configured to receive one or more locking members to secure the plug connector with the complementary receptacle connector when the one or more electrical terminals are engaged with the corresponding one or more electrical contacts to establish the electrical connection therebetween.

18. The work machine of claim 16, wherein the body includes a mating surface, and an inner cavity defined between the outer periphery and the mating surface to receive the one or more electrical terminals extending through the mating surface, the plug connector including:
a cap moveable between an uncovered position and a covered position, wherein:
at the uncovered position, the cap is configured to allow the engagement of the one or more electrical terminals with the corresponding one or more electrical contacts to establish the electrical connection therebetween, and
at the covered position, the cap is configured to sealably close the inner cavity when the one or more electrical terminals of the plug connector are disengaged with the corresponding one or more electrical contacts of the complementary receptacle connector.

19. The work machine of claim 18, wherein the plug connector includes a protruded portion extending outwardly from the outer periphery and defining an eyelet, wherein the cap is pivotably coupled to the protruded portion to move between the covered position and the uncovered position, and wherein the eyelet is configured to receive one or more locking members to lock the cap at the uncovered position.

20. The work machine of claim 16, wherein the cover is pivotably coupled at its first portion to the outer periphery, the cover including a through-hole defined at a second portion distant from the first portion, wherein:
at the first position of the cover, the through-hole is configured to align with a mounting hole defined at the body and receive a fastener therethrough to couple the cover to the outer periphery, and
at one of the plurality of second positions of the cover, the through-hole is configured to retain the fastener when the cover is decoupled from the outer periphery for performing the absence of voltage test of the plurality of electrical connections.
